(19) United States
(12) Patent Application Publication
(10) Pub. No.: US 2010/0065761 A1
(43) Pub. Date: Mar. 18, 2010

(54) ADJUSTABLE DEFLECTION OPTICS FOR ION IMPLANTATION

(75) Inventors: Michael A. Graf, Belmont, MA (US); Bo H. Vanderberg, Gloucester, MA (US); Edward Eisner, Lexington, MA (US)

Correspondence Address: ESCHWEILER & ASSOCIATES, LLC;NATIONAL CITY BANK BUILDING, 629 EUCLID AVE., SUITE 1000, CLEVELAND, OH, 44114, US

(73) Assignee: Axcelis Technologies, Inc., Beverly, MA (US)

(21) Appl. No.: 12/212,507

(22) Filed: Sep. 17, 2008

(51) Int. Cl. H01J 37/08; H01J 3/14

(52) U.S. Cl. 250/492.21; 250/396 R

(57) ABSTRACT

A deflection component suitable for use in an ion implantation system comprises multiple electrodes that can be selectively biased to cause an ion beam passing therethrough to bend, deflect, focus, converge, diverge, accelerate, decelerate, and/or decontaminate. Since the electrodes can be selectively biased, and thus one or more of them can remain unbiased or off, the effective length of the beam path can be selectively adjusted as desired (e.g., based upon beam properties, such as energy, dose, species, etc.).

### FIELD

The present invention is directed to ion implantation systems, and more particularly pertains to deflection optics in ion implantation systems.

### BACKGROUND

Ion implanters are advantageous because they allow for precision with regard to the quantity or concentration of dopants implanted into a workpiece, as well as to the placement of dopants within the workpiece. In particular, ion implanters allow the dose and energy of implanted ions to be varied for given applications. Ion dose controls the concentration of implanted ions, where high current implanters are typically used for high dose implants, and medium current implanters are used for lower dose applications. Ion energy is used to control the junction depth or the depth to which ions are implanted into a semiconductor workpiece.

It can be appreciated that given the trend in the electronics industry to scale down electronic devices to produce smaller, yet more powerful devices (e.g., cell phones, digital cameras, etc.), that the semiconductors and integrated circuits (e.g., transistors, etc.) utilized in these devices are continually being reduced in size. The ability to “pack” more of these devices onto a single semiconductor substrate, or portion thereof (known as a die) also improves fabrication efficiency and yield. It can be appreciated that reducing the energy of the ion beam may allow implants to be performed to shallower depths to produce thinner devices and enhance packing densities. It can also be appreciated that increasing the dose in shallower implants can facilitate desired conductivity, and that beam current of lower energy ion beams may have to increase to facilitate increased packing densities. In other instances, it may be desirable to use a higher energy beam to selectively implant ions relatively deeply into the substrate, so as to create volumes with varying semiconducting properties (e.g., diodes) and/or to tailor the field distribution between different regions or devices in the substrate. Presently different tools (e.g., medium current vs. high current implanters) are used for these different applications.

It can be appreciated that it would be desirable at least for economic reasons to have a single ion implantation system perform a wide range of ion implants. However, low energy or high current implanters typically are made to have a short beam path, while high energy and medium current implanters typically have relatively longer beam paths. Low energy implanters are made short to, among other things, mitigate beam blow up, or the tendency for the beam to expand radially outwardly since it comprises like charged particles that repel one another. High energy implanters, on the other hand, comprise a stream of quickly moving particles that have substantial momentum. These particles have gained their momentum by passing thru one or several acceleration gaps which add to the length of the beam line. Furthermore, to modify the trajectory of particles that have acquired substantial momentum, a focusing element has to be relatively long to apply a sufficient focusing force. Thus, high energy beamlines are made relatively longer than low energy or high current beam lines. Accordingly, there is a need to provide an arrangement that allows the effective length of at least some components of an ion implantation system to be adjusted.

### SUMMARY

The following presents a simplified summary in order to provide a basic understanding of some aspects of the disclosure. This summary is not an extensive overview, and is intended neither to identify key or critical elements nor to delineate the scope of the claimed subject matter. Rather, its primary purpose is merely to present one or more concepts in a simplified form as a prelude to the more detailed description that is presented later.

An electric and/or magnetic deflection component suitable for use in an ion implantation system comprises multiple electrodes that can be selectively biased to cause an ion beam passing therethrough to bend, deflect, decontaminate, focus, accelerate, decelerate, converge and/or diverge. Since the electrodes can be selectively biased, and thus one or more of them can remain unbiased or off, the effective length of a deflection region of the beam path within the electric component can be selectively adjusted as desired, e.g., based upon beam properties, such as energy, dose, species, etc.

In one embodiment, an ion implantation system comprises an ion beam source for generating an ion beam and a component for mass resolving the ion beam. Additionally, the implantation system comprises at least one deflection component that is variably adjustable downstream of the mass resolving component for deflecting the beam to an effective length and an endstation located downstream of the deflection component and configured to support a workpiece that is to be implanted with ions by the ion beam. The deflection component comprises a first electrode, a second electrode defining a gap with the first electrode, and a biasing element for applying an electric voltage to at least one of the first and second electrodes. An electric field is developed between the first and second electrodes to deflect ions of the ion beam traveling through the gap. At least one of the first and second electrodes is segmented to create a plurality of electrode segments along the path of travel of the beam and each electrode segment can be independently biased for selectively controlling an effective length of the deflecting component.

In another embodiment, the implantation system comprises a measurement component configured to measure one or more beam characteristics and a controller operatively coupled to the measurement component, beam generating component, mass resolving component and deflection component and configured to adjust the operation of at least one of the beam generating component, mass resolving component and deflection component in response to measurements taken by the measurement component. The measurement component is configured to measure at least one of current, mass, voltage, and/or charge current. The ion beam may be deflected by the deflection component while concurrently being decelerated by the deflection component. Alternatively, the ion beam is deflected by the deflection component while concurrently being focused by the deflection component.

To the accomplishment of the foregoing and related ends, the following description and annexed drawings set forth in detail certain illustrative aspects and implementations. These are indicative of but a few of the various ways in which one or more aspects may be employed. Other aspects, advantages and novel features will become apparent from the following detailed description when considered in conjunction with the annexed drawings.

### BRIEF DESCRIPTION OF THE DRAWINGS

FIG. 1 is a block diagram illustrating an exemplary ion implantation system wherein electrodes of a deflector can be selectively activated to adjust an effective length therein.

FIG. 2 is a block diagram illustrating an exemplary ion implantation system wherein electrodes of a deflector can be selectively activated to adjust an effective length therein.

FIGS. 3a-3c are illustrations depicting electrodes in a deflector as described herein.

FIG. 4 is an exemplary methodology for exercising control over an ion beam as described herein.

### DETAILED DESCRIPTION

The claimed subject matter is now described with reference to the drawings, wherein like reference numerals are used to refer to like elements throughout. In the following description, for purposes of explanation, numerous specific details are set forth in order to provide a thorough understanding of the claimed subject matter. It may be evident, however, that the claimed subject matter may be practiced without these specific details. In other instances, well-known structures and devices are shown in block diagram form in order to facilitate describing the claimed subject matter.

The present invention pertains to a segmented deflector mechanism that provides for independently and spatially controlling an intensity and geometry of a deflection field as a function of at least one of: beam energy, current, voltage, mass, and/or charge. The segmented deflector mechanism can comprise a first electrode and a second electrode, at least one comprising electrode segments capable of being biased all together or as individually selected while other electrode segments of the deflector are held to a predetermined voltage (e.g., ground). By selectively biasing all, one, or some of the electrode segments an electric field can be maintained in order to tune the amount of deflection and distribution of beam plasma. In this manner, beam neutralization can be maintained while still deflecting a beam of high energy and/or low energy. The present invention is applicable to various types of beam implantation systems, such as both pencil beam and ribbon beam implantation systems.

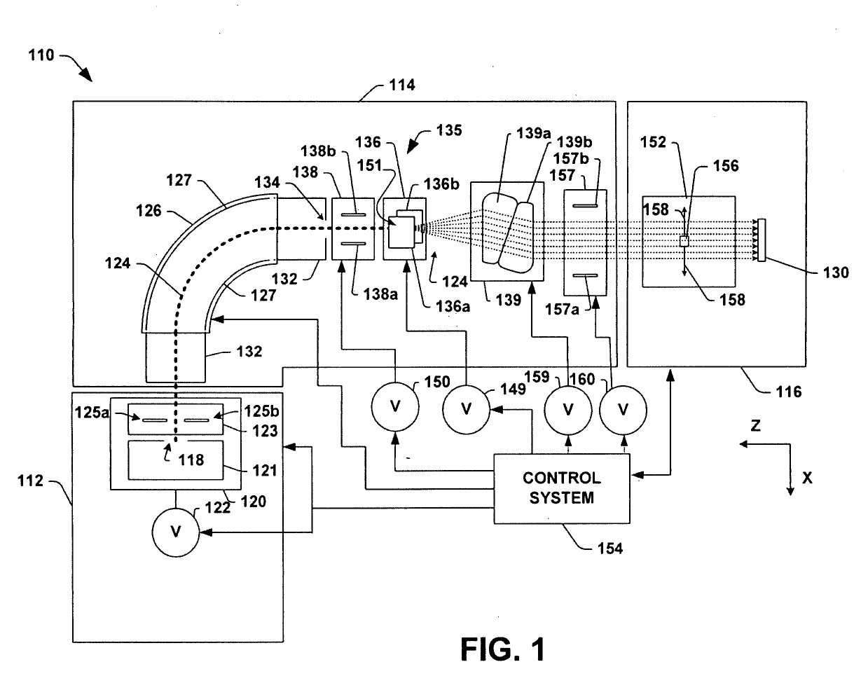

FIG. 1 illustrates an exemplary ion implantation system 110 wherein an ion beam can be transported as described herein. The system 110 has a terminal 112, a beamline assembly 114, and an end station 116. In one embodiment, the terminal 112 includes an ion source 120 powered by a high voltage power supply 122 that produces and directs an ion beam 124 to the beamline assembly 114. The ion source 120 generates charged ions that are extracted and formed into the ion beam 124, which is directed along a beam path in the beamline assembly 114 to the end station 116.

To generate the ions, a gas of a dopant material (not shown) to be ionized is located within a generation chamber 121 of the ion source 120. The dopant gas can, for example, be fed into the chamber 121 from a gas source (not shown). In addition to the power supply 122, it will be appreciated that any number of suitable mechanisms (not shown) can be used to excite free electrons within the ion generation chamber 121, such as RF or microwave excitation sources, electron beam injection sources, electromagnetic sources and/or a cathode which creates an arc discharge within the chamber, for example. The excited electrons collide with the dopant gas molecules and ions are generated thereby. Generally, positive ions are generated although the disclosure herein is applicable to systems wherein negative ions are generated as well. The ions are controllably extracted through a slit 118 in the chamber 121 by an ion extraction assembly 123, which comprises a plurality of extraction and/or suppression electrodes 125a-125b. The extraction assembly 123 can include, for example, a separate extraction power supply (not shown) to bias the extraction and/or suppression electrodes 125a-125b to accelerate the ions from the generation chamber 121.

In one example, the beamline assembly has a beam guide, a mass analyzer, a scanning system, and at least one deflector. In another example, as shown in FIG. 1, the beam line assembly 114 also includes a parallelizer 139, a beam scanning system 135 and the at least one deflector 157. In one embodiment, the mass analyzer 126 is formed at about a ninety-degree angle and comprises one or more magnets (not shown) that serve to establish a (dipole) magnetic field therein. As the beam 124 enters the mass analyzer 126, it is correspondingly bent by the magnetic field such that ions of an inappropriate charge-to-mass ratio are rejected. More particularly, ions having too great or too small a charge-to-mass ratio are deflected into side walls 127 of the mass analyzer 126. In this manner, the mass analyzer 126 allows only those ions in the beam 124 which have the desired charge-to-mass ratio to pass therethrough and exit through a resolving aperture 134. It will be appreciated that ion beam collisions with other particles in the system 110 can degrade beam integrity. Accordingly, one or more pumps (not shown) may be included to evacuate, at least, the beamguide 132 and mass analyzer 126.

The scanning system 135 in the illustrated example of FIG. 1 may include a scanning element 136 and a deflection component 138. Respective power supplies 149 and 150 are operatively coupled to the scanning element 136 and the deflection element 138, and more particularly to respective electrodes 136a, 136b, 138a, and 138b located therein. The deflection component 138 receives the mass analyzed ion beam 124 having a relatively narrow profile (e.g., a “pencil” beam in the illustrated system 110), and a voltage applied by the power supply 150 to the plurality of electrodes 138a and 138b operates to focus, steer and deflect the beam to the scan vertex 151 of the scanning element 136. Alternatively, a ribbon beam may also be received by the deflection components described herein. In the case of a pencil beam, a voltage waveform applied by the power supply 149 (which theoretically could be the same supply as 150) to the scanner plates 136a and 136b then scans the beam 124 back and forth to spread the beam 124 out into an elongated “ribbon” beam (e.g., a scanned beam 124), having a width that may be at least as wide as or wider than the workpieces of interest. It will be appreciated that the scan vertex 151 can be defined as the point in the optical path from which each beamlet or scanned part of the ribbon beam appears to originate after having been scanned by the scanning element 136. In an embodiment using solely a pencil beam, the scanning element 136 may be discarded or deactivated.

In one example, the scanned beam 124 is then passed through a particle trap (not shown) to decontaminate the beam, which may contain a number of different traps using electric and/or magnetic fields. In another example, the scanned beam is passed through a parallelizer 139, which comprises two dipole magnets 139a, 139b in the illustrated example.

It will be appreciated that different types of end stations 116 may be employed in the implanter 110. The end station 116 in the illustrated example is a “serial” type end station that supports a single workpiece 130 along the beam path for implantation. A dosimetry system 152 can also be included in the end station 116 near the workpiece location for calibration measurements prior to (and also throughout) implantation operations. In one embodiment, during calibration, the beam 124 passes through the dosimetry system 152. The dosimetry system 152 includes one or more profilers 156 that may traverse a profiler path 158, thereby measuring the profile of the beam. The profiler 156 may comprise a current density sensor, such as a Faraday cup, for example, and the dosimetry system can, in one example, measure both beam density distribution and angular distribution as described in R. D. Rathmell, D. E. Kamenitsa, M. I. King, and A. M. Ray, IEEE Proc. of Intl. Conf. on Ion Implantation Tech., Kyoto, Japan 392-395 (1998), U.S. Pat. No. 7,329,882 to Rathmell et al. entitled ION IMPLANTATION BEAM ANGLE CALIBRATION and U.S. Pat. No. 7,361,914 to Rathmell et al. entitled MEANS TO ESTABLISH ORIENTATION OF ION BEAM TO WAFER AND CORRECT ANGLE ERRORS the entirety of which are hereby incorporated herein by reference.

The dosimetry system 152 is operably coupled to a control system 154 to receive command signals therefrom and to provide measurement values thereto. For example, the control system 154, which may comprise a computer, microprocessor, etc., may be operable to take measurement values from the dosimetry system 152 and calculate a current density, an energy level and/or an average angle distribution of the beam, for example. The control system 154 can likewise be operatively coupled to the terminal 112 from which the beam of ions is generated, as well as the mass analyzer 126 of the beamline assembly 114, parallelizer 139, and the deflectors of 136, 138 and 157 (e.g., via power supplies 149, 150, 159, 160).

In one embodiment, one or more deflection stages 157 can be located downstream of the mass analyzer 126. Up to this point in the system 110, the beam 124 is generally transported at a relatively high energy level, which mitigates the propensity for beam blow up, especially where beam density is elevated such as at the resolving aperture 134. Similar to the ion extraction assembly 123, scanning element 136 and focusing and steering element 138, the deflection stage 157 comprises one or more electrodes 157a, 157b operable to decelerate the beam 124.

It will be appreciated that while two electrodes 125a and 125b, 136a and 136b, 138a and 138b and 157a and 157b are respectively illustrated in the exemplary ion extraction assembly 123, scanning element 136, deflection component 138 and deflection stage 157, that these elements 123,136,138 and 157 may comprise any suitable number of electrodes arranged and biased to accelerate and/or decelerate ions, as well as to focus, bend, deflect, converge, diverge, scan, parallelize and/or decontaminate the ion beam 124 in a manner substantially similar to that provided in U.S. Pat. No. 6,777,696 to Rathmell et al. the entirety of which is hereby incorporated herein by reference. Additionally, the focusing and steering element 138 may comprise electric deflection plates (e.g., one or more pairs thereof), as well as an Einzel lens, quadrupoles and/or other focusing elements to focus the ion beam. Although not necessary it can be advantageous to apply voltages to the deflecting plates within element 138 so that they average to zero, the effect of which is to avoid having to introduce an additional Einzel lens to mitigate the distortion of the focusing aspect of element 138. It will be appreciated that “steering” the ion beam is a function of the dimensions of deflection electrodes of 138a, 138b and the steering voltages applied thereto, among other things, as the beam direction is proportional to the steering voltages and the length of the plates, and inversely proportional to the beam energy.

By way of further example, it will be appreciated that the deflection component 157 of FIG. 1 works to further filter ions of a non-desired energy and neutrals out of the beam. Conversely, ion species of the desired energy will follow the same path and be directed, bent, deflected, converged, focused, accelerated, decelerated, and/or decontaminated by the deflection component 157. This is advantageous if the ion beam comprises molecules of similar masses, such as in cluster beam implantation wherein substantially all masses follow the same trajectories and the deceleration stage has little to no mass-dispersion, such that beam size and angle (in this example, out of the plane of the ribbon) is maintained.

In one embodiment, the deflector 157 can comprise multiple electrodes such as a first electrode 157a and a second electrode 157b that can comprise at least one upper electrode and at least one lower electrode respectively that has a deflection region of a certain effective length (not shown) and can be selectively biased to bend, deflect, converge, diverge, focus, accelerate, decelerate, and/or decontaminate the ion beam 124. The deflection region of the deflector 157 comprises the region where electric fields act upon the beam in a manner operable to induce bending of the beam. For example, the effective length of the deflection region can vary depending upon the amount of electric field space produced, as will be discussed further infra. A power supply 160 can be operatively coupled to the deflection component 157 to selectively bias the electrodes. It will be appreciated that the effective length of the deflection region of deflector 157 can be adjusted by selectively biasing the electrodes. For example, the effective length of the deflector 157 can be decreased by biasing one or more of the electrodes to the same electric potential as the surrounding of the implanter (e.g., zero or ground), which essentially deactivates or turns off those electrodes. Similarly, the effective length of the deflector 157 can be increased by biasing the electrodes to a deflecting potential (typically different from zero or ground) to thereby enlarge the electric field generated by the electrodes therein.

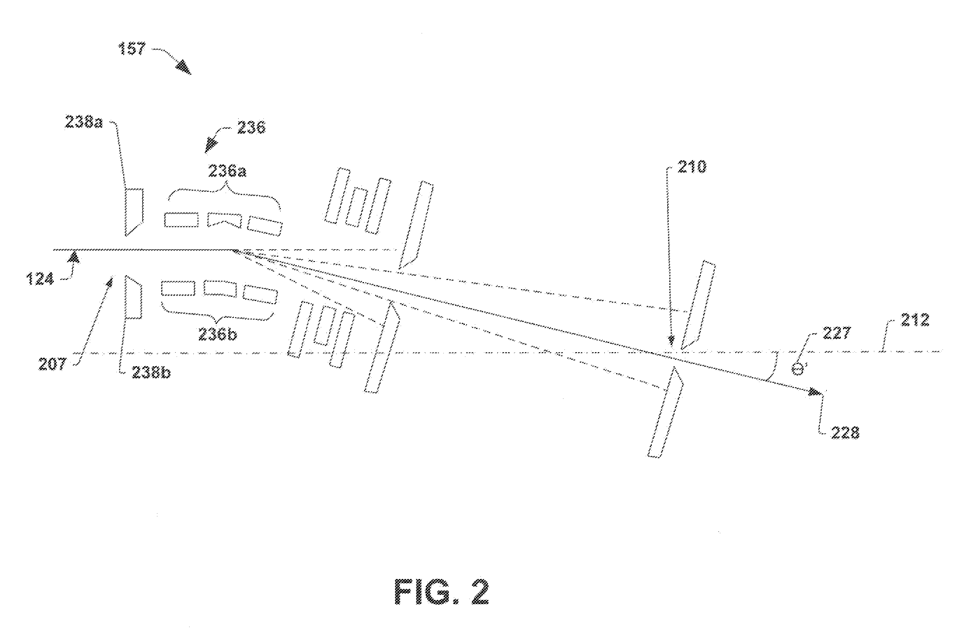

Turning to FIG. 2, in one embodiment, a deflection stage 157 is illustrated in greater detail, and includes first 238a and second 238b vertical plates that prevent beam splice onto a deflection component 236 located downstream. The deflection component 236 comprises an upper electrode 236a and a lower electrode 236b respectively having a plurality of electrode segments. In this embodiment, the beam 124 may be decelerated or accelerated before, during and/or after the bending of the beam 124 by the deflection component 236.

FIG. 2 is only one example of the location where the beam 124 may be deflected by the deflector 157 (as shown in FIG. 1) while concurrently being decelerated, and is among several various arrangements that are contemplated in a manner substantially similar to that provide in U.S. Pat. No. 7,102,146 to Rathmell the entirety of which is hereby incorporated herein by reference. In another example, the beam 124 may concurrently be accelerated while being deflected and may occur after, before and/or during bending of the beam to guide charged particles along a devised pathway. Any ion that is not charged or is the wrong charge does not follow that path, and therefore, proceeds in a different direction, which may be into a neutral trap, for example.

In the illustrated example, the ion beam 124 passing through an aperture 210 can be deflected from the axis 212 by an angle θ′ 227 which may be between about 7 and 20 degrees, about 12 degrees for example, and can be focused at a point 228 downstream from the aperture 210. FIG. 2 illustrates a hybrid type of scan mechanism, alternatively there are other types of scan mechanisms that can be embodied herein, such as solely a pencil beam. As discussed above, the beam may comprise any number of beam types including, but not limited to, a standard beam line with an end station after the mass analyzer without any scanning type mechanism. Further, a scanner could be present to provide a scanned beam, such as a scanned ribbon beam (i.e., a time-average ribbon that is a hybrid scan), a real-time static ribbon beam, or any other type of ribbon beams provided by various arrangements.

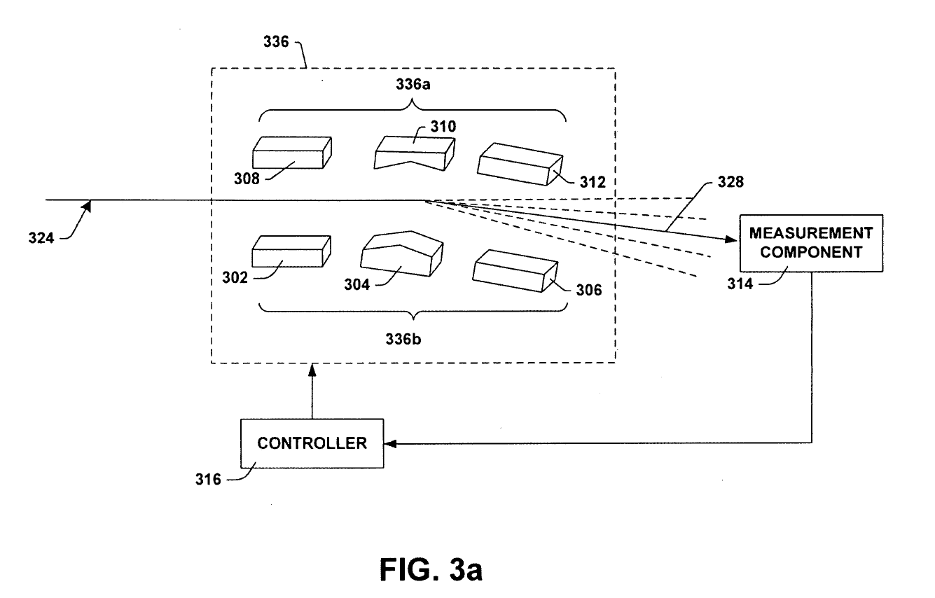

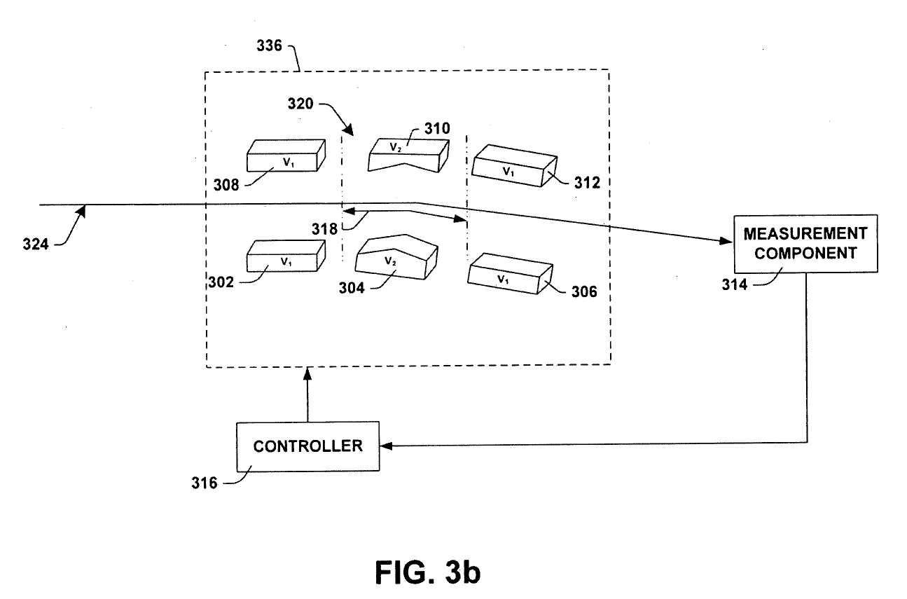

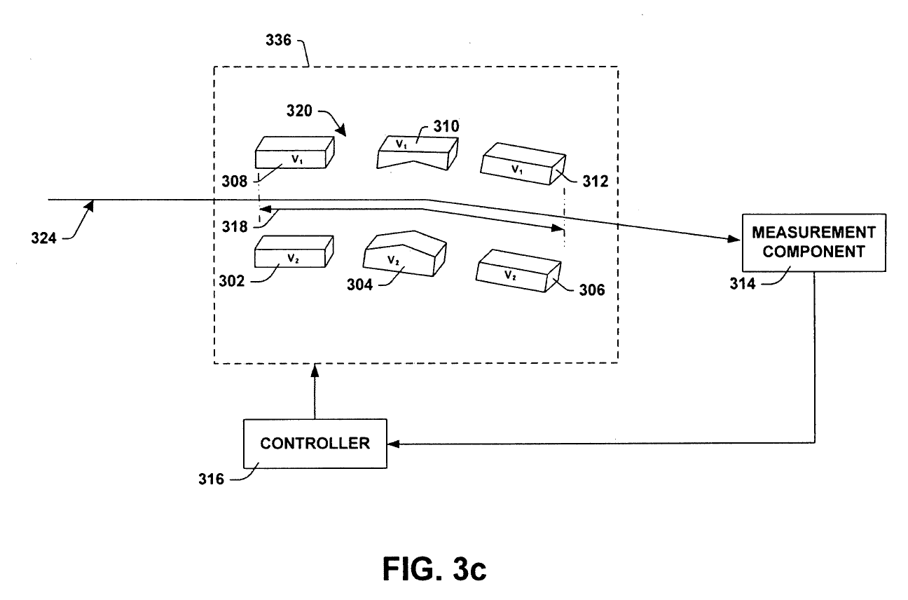

FIG. 3a illustrates one embodiment of a segmented deflection mechanism 336 that can be representative of the deflection component 226 of FIG. 2. The segmented deflection mechanism 336 can comprise an upper electrode assembly 336a and a lower electrode assembly 336b that respectively comprise an arrangement of electrode segments 302, 304,306, 308, 310, and 312 arranged in a beam direction, indicated at 328. The electrodes 302, 304, and 306 form the lower electrode assembly 336b and the electrodes 308, 310, and 312 form the upper electrode assembly 336a. In another example, a beam 324 may concurrently be decelerated/accelerated while being deflected and may occur after, before and/or during bending of the beam to guide charged particles along a devised pathway.

The electrode segments of the segmented deflection mechanism can each be independently biased for selectively controlling an effective length of the deflecting component. The deflection mechanism 336 can be coupled to a controller 316 and a measurement component 314 configured to measure one or more beam characteristics that can comprise at least one of energy, voltage, current, current density, mass, charge, and species of the beam 324. The controller can be operatively coupled to the measurement component, beam generating component, mass resolving component and/or deflection component and configured to adjust the operation of at least one of the beam generating component, mass resolving component and deflection component in response to measurements taken by the measurement component.

In one embodiment, illustrated in FIG. 3b, the first and last respective pairs of upper and lower electrodes 302, 308, 306 and 312 of the deflection component 336 can be maintained at a potential V₁ of about 0 volts to negative 2 kilovolts, to repel electrons in the ion beam such that they do not enter the deflection region. This is desirable because the upper and lower middle electrodes 310 and 304 respectively may be biased to a relatively high positive potential V₂ in order to generate deflection; the upper middle electrode 310 can be biased to a high positive voltage, for example. A deflection region 320 is produced therein that is delineated as an approximate effective length 318. This can be performed for high energy beams. The effective length 318 by which the deflection region 320 interacts with the ion beam is approximated due to the various non-linear geometries of interacting electric field lines and thus an approximate length is depicted; however, the effective length may take on various geometries and lengths in relation to the amount of biasing and selectivity of the individual electrode segments.

Alternatively, any one of the electrode segments depicted can be independently biased for selectively controlling the effective length 318 of the deflection region 320. This can be useful when trying to keep the deflection region 320 where the electric field acts upon the beam as short as possible by not using as many positive voltages, for example. In other words, a number of electrode segments that are less than all of the segments of an upper or lower electrode (e.g., one out of three, two out of three) can be utilized for low energy beams to make the electric field space (which can strip away plasma from the beam) to be physically shorter. Similar to FIG. 3a the deflection mechanism 336 can be coupled to a controller 316 and a measurement component 314 configured to measure one or more beam characteristics that can comprise at least one of energy, voltage, current, current density, mass, charge, and species of the beam 324.

FIG. 3c illustrates an embodiment where high energy beams can be utilized. In one embodiment, all three of the upper electrode segments can be biased to high voltages V₁ and the three lower electrode segments to lower voltages V₂. This can effectively strip beam plasma, and therefore, provide an even longer effective length 318 of the deflection region 320. Once again, the effective length 318 by which the deflection region 320 interacts with the ion beam is approximated due to the various non-linear geometries of interacting electric field lines and thus an approximate length is depicted; however, the effective length may take on various geometries and lengths in relation to the amount of biasing and selectivity of the individual electrode segments. For example, in FIG. 3c the effective length 318 may be an approximate length substantially similar to the physical length of the beam line passing there thru. Although the effective length illustrated may be substantially similar in length at points within the deflection region, there may be points that are substantially different in length in relation to the beam line as well.

Other biasing configurations can be utilized as well where individual electrode segments of the segmented deflection mechanism are selectively biased. For example, all the electrode segments can be grounded except the middle lower electrode 304, which may be biased negative. In this case, the bending action is provided still because the lower negative electrode is attracting the ion beam. This can be provided for low energy beams in order to get a better distribution of beam plasma to promote ion beam neutralization. Other electrode segments of the deflection component can be configured to be selectively biased independently of one another. This can be performed through a power source (not shown) coupled to a controller 316 that has received measurements from the measurement component 316 of the beam based on at least one of energy, current, mass and charge.

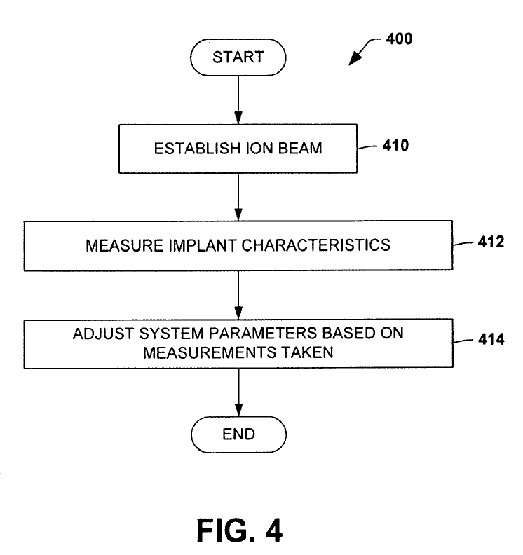

Turning to FIG. 4 an exemplary methodology 400 is illustrated for controlling an ion beam in an ion implantation system as described herein. Although the methodology 400 is illustrated and described hereinafter as a series of acts or events, it will be appreciated that these are not to be limited by the illustrated ordering. For example, some acts may occur in different orders and/or concurrently with other acts or events apart from those illustrated and/or described. In addition, not all illustrated acts may be required to implement one or more aspects of the embodiments of the description herein. Further, one or more acts can be carried out in one or more separate acts and/or phases.

The method 400 begins at 410 where an ion beam that is utilized to implant ions into a workpiece is generated in the ion implantation system. The beam is, for example, established to have a desired dopant species, energy and/or current. The method then advances to 412 where one or more implantation characteristics are measured, such as implant angle, beam species, beam energy, beam dose, etc. Such characteristics may be measured with a dosimetry system as described above, for example. More particularly, a dosimetry system may be utilized that determines the current density of the beam, for example. The measured characteristics can be compared to desired values stored in a control component of the system, for example, to ascertain what adjustments, if any, need to be made to obtain the desired result.

The operation of the system is then adjusted at 414 based upon the measurements taken at 412. For example, any one or more of the electrode segments of a deflection component may be adjusted as described above to obtain desired ion implantation. Bias voltages, for example, to be applied to one or more electrodes to achieve a desired effective length, degree of deflection and/or level of acceleration/deceleration can be obtained, for example. The method 400 is illustrated as ending thereafter, but may in fact continue to cycle through or be repeated to achieve desired ion implantation.

Although the disclosure has been shown and described with respect to one or more implementations, equivalent alterations and modifications will occur to others skilled in the art based upon a reading and understanding of this specification and the annexed drawings. The disclosure includes all such modifications and alterations and is limited only by the scope of the following claims. In particular regard to the various functions performed by the above described components (assemblies, elements, devices, circuits, etc.), the terms (including a reference to a “means”) used to describe such components are intended to correspond, unless otherwise indicated, to any component which performs the specified function of the described component (i.e., that is functionally equivalent), even though not structurally equivalent to the disclosed structure which performs the function in the herein illustrated exemplary implementations. In addition, while a particular feature may have been disclosed with respect to only one of several implementations, such feature may be combined with one or more other features of the other implementations as may be desired and advantageous for any given or particular application. Furthermore, to the extent that the terms “includes”, “having”, “has”, “with”, or variants thereof are used in either the detailed description or the claims, such terms are intended to be inclusive in a manner similar to the term “comprising.” Also, “exemplary” as utilized herein merely means an example, rather than the best.

What is claimed is:

1. An ion implantation system, comprising:
an ion beam source configured to generate an ion beam;
a mass analyzer for mass analyzing the ion beam generated;
a deflection component downstream of the mass analyzer and having a deflection region associated therewith for deflecting the ion beam as mass analyzed; and
an endstation located downstream of the deflection component and configured to support a workpiece that is to be implanted with ions by the ion beam;
wherein the deflection component is configured to vary a length of the deflection region.

2. The ion implantation system of claim 1, wherein the deflection component comprises:
a first electrode;
a second electrode defining a gap with the first electrode; and
a biasing element for applying an electric voltage to at least one of the first electrode and second electrode;
wherein an electric field is developed between the first electrode and the second electrode to deflect ions of the ion beam traveling through the gap;
wherein at least one of the first electrode and the second electrode is segmented to create a plurality of electrode segments along a path of travel of the ion beam; and
wherein each electrode segment can be independently biased for selectively controlling the length of the deflection component.

3. The ion implantation system of claim 2, wherein one or more of the plurality of electrode segments comprises an upper and a lower electrode opposed to one another across an electrode gap and wherein an upper electrode is segmented into at least three segments and a lower electrode is segmented into at least three segments.

4. The ion implantation system of claim 2, wherein a first segment and a last segment of
an upper electrode and a lower electrode are biased to provide a negative potential distribution with respect to the surrounding in the gap between the first segment of the upper electrode and the first segment of the lower electrode and between the last segment of the upper electrode and the last segment of the lower electrode.

5. The ion implantation system of claim 3, wherein at least one electrode segment between a first electrode segment and a last electrode segment of the upper electrode are biased positive and at least one electrode segment between a first electrode segment and a last electrode segment of the lower electrode are biased more negative than respective segments of the upper electrode.

6. The ion implantation system of claim 3, wherein a middle segment of the lower electrode is biased negatively while remaining segments and the upper electrode are at ground potential with respect to the surrounding such as to minimize the length of the deflection region of the deflection component.

7. The ion implantation system of claim 1, further comprising:
a measurement component configured to measure one or more ion beam characteristics; and
a controller operatively coupled to the measurement component, the ion beam source, the mass analyzer and the deflection component and configured to adjust operation of at least one of the ion beam source, the mass analyzer and the deflection component in response to measurements taken by the measurement component;
wherein ion beam characteristics measured by the measurement component comprise at least one of voltage, current, mass, charge, energy, and species of the ion beam.

8. The ion implantation system of claim 1, further comprising: a parallelizer component for bending the ion beam into a substantially s shape to filter out contaminants while concurrently parallelizing the ion beam into a plurality of parallel beamlets such that beamlets respectively have a substantially equal effective length.

9. The ion implantation system of claim 1, wherein the ion beam is deflected by the deflection component while concurrently being decelerated, focused, or decelerated and focused by the deflection component.

10. The ion implantation system of claim 1, further comprising:
a measurement component configured to measure one or more ion beam characteristics; and
a controller operatively coupled to the measurement component and a focusing lens for acceleration or deceleration of the ion beam in response to measurements taken by the measurement component.

11. An electric deflection apparatus for use in a beam line within an ion implantation system, comprising:
an electric deflection component comprising a deflection region that is operable to deflect an ion beam;
wherein the electric deflection component is configured to vary a length of the deflection region.

12. The electric deflection apparatus of claim 11, wherein the electric deflection component comprises:
a first electrode;
a second electrode defining a gap with the first electrode; and
a biasing element for applying an electric voltage to at least one of the first electrode and the second electrode;
wherein an electric field is developed between the first electrode and the second electrode to deflect ions of the ion beam traveling through the gap;
wherein at least one of the first electrode and the second electrode is segmented to create a plurality of electrode segments along a path of travel of the ion beam;
wherein respective electrode segments can be independently biased for selectively controlling the length of the deflection region.

13. The electric deflection apparatus of claim 12, further comprising:
a measurement component configured to measure one or more beam characteristics; and
a controller operatively coupled to the measurement component and the electric deflection component, and configured to adjust operation of the electric deflection component in response to measurements taken by the measurement component by independently biasing each electrode segment to selectively control the length of the deflection region therein.
wherein beam characteristics measured by the measurement component comprise at least one of voltage, current, mass, charge, energy, and species of the ion beam.

14. The electric deflection apparatus of claim 11, wherein the ion beam is deflected by the electric deflection component while concurrently being decelerated, focused, or decelerated and focused by the electric deflection component.

15. The electric deflection apparatus of claim 12, wherein one or more of the plurality of electrode segments comprises an upper and a lower electrode opposed to one another across an electrode gap and wherein an upper electrode is segmented into at least three segments and a lower electrode is segmented into at least three segments.

16. A method of implanting ions into a workpiece in an ion implantation system, comprising:
generating an ion beam in the ion implantation system;
measuring one or more beam characteristics of the ion beam;
adapting an effective length of the ion beam traveling through a deflection component in the ion implantation system by selectively adjusting respective bias voltages applied to one or more mid-gap electrodes of the deflection component based upon beam characteristics.

17. The method of claim 16, further comprising:
determining if bias voltages should be applied to one, two or three pairs of electrodes in the deflection component to deflect the ion beam.

18. The method of claim 16, further comprising selectively controlling the effective length of the deflection component.

19. The method of claim 16, further comprising selectively adjusting respective bias voltages to be applied to first and second electrodes of the deflection component to control at least one of convergence, acceleration or deceleration of the ion beam.

20. The method of claim 16, further comprising:
selectively adjusting respective bias voltages to be applied to first and second electrodes of the deflection component to control deflection based on at least one of energy, current and species of the ion beam.
